(19) United States
(12) Patent Application Publication
(10) Pub. No.: US 2008/0192551 A1
(43) Pub. Date: Aug. 14, 2008

(54) COMPLEMENTARY OUTPUT FLIP FLOP

(75) Inventor: Gerd Rombach, Freising (DE)

Correspondence Address: TEXAS INSTRUMENTS INCORPORATED, P O BOX 655474, M/S 3999, DALLAS, TX, 75265, US

(73) Assignee: TEXAS INSTRUMENTS DEUTSCHLAND GMBH, Freising (DE)

(21) Appl. No.: 12/028,652

(22) Filed: Feb. 8, 2008

(30) Foreign Application Priority Data
Feb. 8, 2007 (DE) 10 2007 006 375.1

(51) Int. Cl. G11C 7/10; H03K 3/289

(52) U.S. Cl. 365/189.05; 327/203

(57) ABSTRACT

A flip-flop has a master stage and two slave stages coupled to receive complementary outputs from the master stage. Each stage includes transfer gates and a bistable element in the form of cross-coupled inverters. The master stage bistable element switches states on a first edge of a clock signal in response to the state of a digital data input signal. The slave stage bistable elements switch states on a second dege of the clock signal in response to respective complemenary outputs from the master stage.

This application claims priority from German Patent Application No. 10 2007 006 375.1, filed Feb. 8, 2007.

### FIELD OF THE INVENTION

The invention relates to a flip-flop; and, more specifically, to a flip-flop with a complementary output. The invention relates further to a memory system including a data buffer with a flip-flop having a complementary output.

### BACKGROUND

Flip-flops are well-known in the art and are used as standard cells for all kinds of digital data processing, buffering and storing. Multiple flip-flops are often arranged to form registers, which are used for state machines together with combinatorial logical circuitry. Some applications require flip-flops with a full-swing complementary output signal to provide improved signal integrity. A zero offset and a crossing point of the two complementary output signals at half the supply voltage is often required. A conventional approach for providing complementary output signals consists of coupling an inverter to one output of a flip-flop for providing a complementary output signal by the inverter. However, even in a very fast technology, in which inverters have only minimum delay, the inverter at the output causes a slight timing offset (and maybe other non-idealities) between the two output signals. This effect introduces an asymmetry into the complementary output, with a resulting offset, i.e., a shift of the crossing point of the output signals away from half the supply voltage, and a time shift. The non-idealities introduced by the inverter are also process, temperature and supply voltage dependent.

### SUMMARY

In view of the above considerations, it is an object of the invention to provide a flip-flop with a complementary output having improved offset and crossing point characteristics, which are less dependent on process variations and operating conditions than the conventional flip-flops.

A flip-flop according to described embodiments of the invention includes a clock input for receiving a clock signal, a master stage having a master data input for receiving a digital data input signal, a master data output and a first bistable element; wherein the first bistable element is coupled between the master data input and the master data output and is adapted to switch between one of two states during a first edge of the clock in response to the state of the digital data input signal. Further, the flip-flop according to described embodiments of the invention includes a first slave stage having a first slave data input coupled to the master data output, a slave data output, and a second bistable element coupled between the first slave data input and the slave data output; the second bistable element being adapted to switch during a second edge of the clock in response to the state of the master data output. An inverter is coupled to the master data output, and a second slave stage having a second slave data input is coupled to an output of the inverter. A complementary slave data output and a third bistable element coupled between the second slave data input and the complementary slave data output is also present in the second slave stage. The third bistable element is adapted to switch during the second edge of the clock in response to the state of the output signal of the inverter.

Generally, the flip-flop according to the invention includes a master stage, and two slave stages. The master stage is set to one of two states in response to the input data signal during a first edge (for example, the rising or positive edge) of the input clock. The slave stages are triggered by a second edge of the clock (for example, the falling or negative edge). The inverter for providing the complementary signal is disposed between the master stage and one of the slave stages. Accordingly, the delay and the respective influence of the inverter is moved from the output of the flip-flop in between the two stages. As the two stages are decoupled from each other by use of different edges of a clock, delays and offsets introduced by the inverter are irrelevant for the flip-flop according to the described embodiments. The influence of process variations and operating conditions (supply voltage, temperature, etc.) is reduced as long as the delay of the inverter is kept shorter than half the period the clock, i.e., shorter than the time between the falling and the rising edges. As a consequence, the crossing point of the complementary output signals will be synchronous and at half the supply voltage, and any offset of the complementary output signal can be minimized.

The described flip-flop may be further improved by matching the components of the first and second slave stages, such that the electrical characteristics of the two slave stages are almost identical. Matching the components of the two slave stages will further improve symmetry of the complementary output. An exact matching will provide almost identical timing of the two slave stages in response to the clock, and thereby optimum offset and crossing point characteristics.

The first slave and the second slave may preferably be implemented as bistable elements with two cross-coupled inverters, with the output of one inverter coupled to the input of the respective other inverter through a transfer gate. This approach provides efficient control of the state of the bistable element, in particular for an edge triggered flip-flop. In particular, if the master stage is implemented in substantially the same way as the slave stages, however with inverted clock inputs to the transfer gates, the rising edge of the input clock may be used to trigger the master stage and the falling edge can be used to trigger the two slave stages.

According to a specific implementation, the flip-flop may preferably be a master and slave D-flip-flop. However, other types of flip-flops will equally profit from the invention.

The invention relates also to a memory system including a memory controller and at least one memory board. In an embodiment, the memory board may include a digital data buffer with an output register comprising flip-flops according to the invention and a plurality of RAM modules, wherein digital address and clock signals from the memory controller are applied to each data path of the digital data buffer as digital data input signal and clock input signal, and the data output signals and clock output signals from the digital data buffer are applied in parallel to the RAM modules. As the timing of the digital data and address data signals is an important issue in the such memory systems, the flip-flops according to the invention are very beneficial, particularly if they are inserted as an output register of the data buffer. The data buffer serves to adjust the timing and phase offset of the data and address data from the memory controller before they are conveyed from the output register of the buffer to the RAM modules. DDR3 is a typical application where the above configuration of a memory systems occurs.

### BRIEF DESCRIPTION OF THE DRAWINGS

The new flip-flop architecture and the benefits of the inventive flip-flop will be apparent from the below description of embodiments, taken together with the accompanying drawings, wherein:

FIG. 1 is a simplified schematic of a conventional master and slave D-flip-flop;

FIG. 2 is a simplified schematic of a master and slave D-flip-flop according to an embodiment of the invention; and

FIG. 3 is a schematic block diagram of a memory system in which the flip-flop according to the invention can be used.

### DETAILED DESCRIPTION OF EXAMPLE EMBODIMENTS

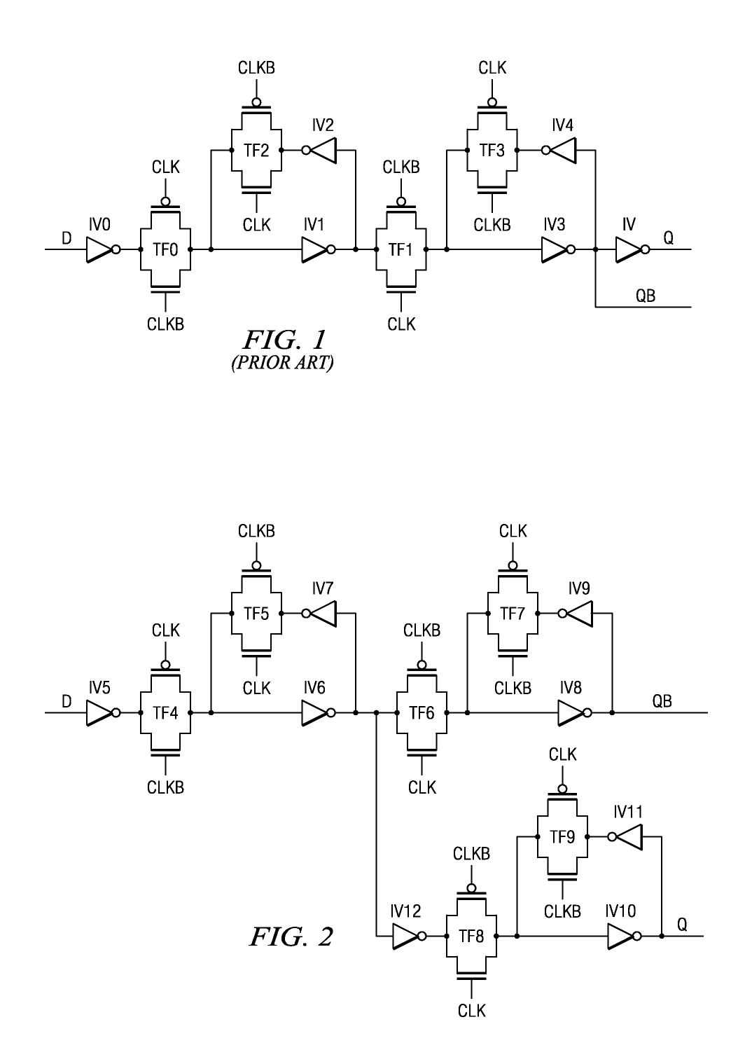

FIG. 1 shows a simplified schematic of a master and slave D-flip-flop according to the prior art. The data signal at input D is inverted by inverter IV0 and passed via transfer gate TF0 to the bistable element of the master stage. The bistable element comprises two cross-coupled inverters IV2, IV1. The signals CLK, CLKB are complementary clock input signals coupled to the pins of the various transfer gates. TF0 is switched on, if CLK is logic LOW and CLKB is logic HIGH. The second transfer gate TF2 opens and closes during complementary half cycles of the input clock CLK. The output of the inverter IV1 is further coupled to another transfer gate TF1 through which the output signal of the master stage is coupled to a second bistable element comprising cross-coupled inverters IV3, IV4. Transfer gates TF1, TF3 of the slave stage open and close in response to the clock signal CLK, but inversely with respect to the master stage. The output signal QB is passed through an output inverter IV for providing two complementary output signals Q, QB. Even in a very fast up-to-date CMOS technology, the delay between the two output signals will be about 50 picoseconds. This delay introduces a timing offset and the position of the crossing point of the two output signals will move away from half the supply voltages. Production spread and process variations as well as varying operating conditions (temperature, supply voltage, etc.) introduce additional variations. The exact timing, the crossing points and offsets of the complementary output signals is difficult to predict. Consequently, respective tolerances and timing margins have to be considered, such that the conventional flip-flop may not be used for high speed applications.

FIG. 2 shows a simplified schematic of a flip-flop according to an embodiment of the invention. In the illustrated arrangement, the flip-flop comprises three almost identical stages. A first master stage includes transfer gates TF4, TF5, as well as cross-coupled inverters IV6, IV7. The data input D is supplied to transfer gate TF4 via inverter IV5. The bistable element of the master stage (first bistable element) is coupled to transfer gates TF6 of a first slave stage, as well as via inverter IV12 to transfer gate TF8 of a second slave stage. The output signal of the master stage is inverted by inverter IV12. The two slave stages comprise the same number and the same kinds of components. The first slave stage includes transfer gates TF6, TF7, as well as cross-coupled inverter elements IV8, IV9 operating as a second bistable element. The transfer gates TF6, TF7 and other transfer gates in FIG. 2 may also be implemented as inverting transfer gates or in still another form. The second slave stage includes transfer gates TF8, TF9, as well as cross-coupled inverters IV10, IV11 which serve as third bistable element. The two slave stages are driven by the same clock signals, i.e., the same edges of the input clock CLK. However, the master stage is triggered by a different edge of the input clock, so the switching of both slave stages and the switching of the master stage are basically decoupled from each other by half the clock period. The delay or other non-idealities of inverter IV12 have no influence on the flip-flop output signals Q, QB as long as half the clock period is long enough. Implementing the slave stages by the same matched components in a CMOS IC reduces the influence of the process variations and different operating conditions. The inverter IV12 changes neither the set-up- and hold-time, nor the maximum operating frequency of the flip-flop.

A preferred application for a flip-flop implemented in accordance with the invention relates to memory systems, in particular to DDR2 or DDR3 memory systems. Flip-flops according to the invention may preferably be used for data buffers for DDR3 applications. Practically, all applications, where a precise output timing, minimum offset, and an optimum crossing point of complementary digital output signals are required will profit from flip-flops implemented in accordance with the invention.

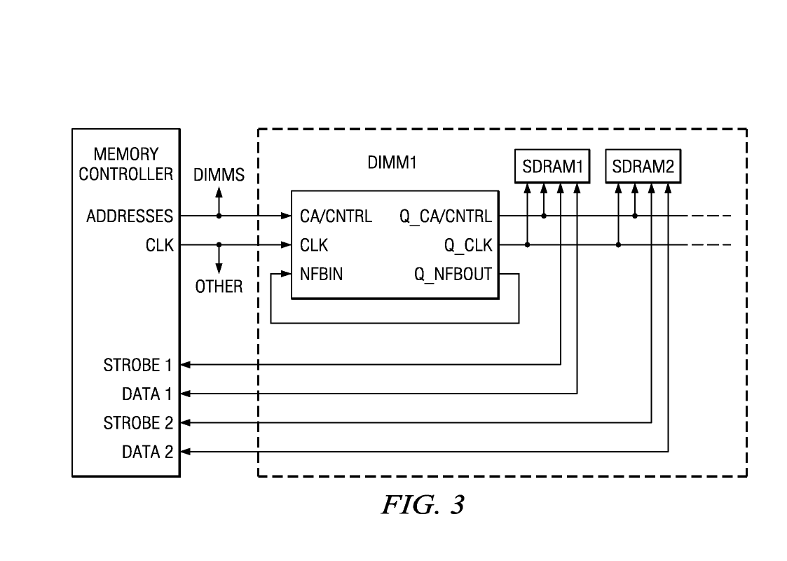

By way of a preferred application, FIG. 3 shows a RAM memory system with a memory controller and a DIMM module which incorporates one of the data buffers including the inventive flip-flops as an output register (referred to as a “registered buffer”), and a plurality of similar memory devices SDRAM1, SDRAM2, . . . , with the obvious option of adding further similar DIMM modules to the memory system. Although only one data path with input signal CA/CNTRL and output signal Q_CA/CNTRL is shown, it should be clear that the signals would be n bits wide.

Those skilled in the art to which the invention relates will appreciate that there are also many other ways to implement the claimed invention.

What is claimed is:

1. A flip-flop, comprising:
a clock input for receiving a clock signal;
a master stage having a master data input for receiving a digital data input signal, a master data output, and a first bistable element; the first bistable element being coupled between the master data input and the master data output, and being adapted to switch between states during a first edge of the clock signal in response to the state of the digital data input signal;
a first slave stage having a first slave data input coupled to the master data output, a slave data output, and a second bistable element; the second bistable element being coupled between the first slave data input and the slave data output, and being adapted to switch between states during a second edge of the clock signal in response to the state of the master data output;
an inverter coupled to the master data output; and
a second slave stage having a second slave data input coupled to an output of the inverter, a complementary slave data output, and a third bistable element; the third bistable element coupled between the second slave data input and the complementary slave data output, and being adapted to switch between states during the second edge of the clock signal in response to the state of the output signal of the inverter.

2. The flip-flop of claim 1, wherein both the first slave stage and the second slave stage comprise matched components to match electrical characteristics.

3. The flip-flop of claim 1, wherein the master, the first slave stage and the second slave stage each comprises two complementary CMOS transfer gates.

4. The flip-flop of claim 3, wherein each bistable element comprises two cross-coupled inverters, the output of one inverter being coupled to the input of the other inverter through a transfer gate.

5. The flip-flop of claim 1, wherein each bistable element comprises two cross-coupled inverters, the output of one inverter being coupled to the input of the other inverter through a transfer gate.

6. The flip-flop of claim 1, wherein the flip-flop is a D-flip-flop.

7. A memory system, comprising:
a memory controller; and
at least one memory board comprising a digital data buffer with a flip-flop and a plurality of RAM modules;
wherein digital address and clock signals from the memory controller are applied as digital data input and clock input signals to the digital data buffer, and data output signals and clock output signals from the digital data buffer are applied in parallel to the RAM modules; and
wherein the flip-flop comprises:
a clock input for receiving a clock signal;
a master stage having a master data input for receiving a digital data input signal, a master data output, and a first bistable element; the first bistable element being coupled between the master data input and the master data output, and being adapted to switch between states during a first edge of the clock signal in response to the state of the digital data input signal;
a first slave stage having a first slave data input coupled to the master data output, a slave data output, and a second bistable element; the second bistable element being coupled between the first slave data input and the slave data output, and being adapted to switch between states during a second edge of the clock signal in response to the state of the master data output;
an inverter coupled to the master data output; and
a second slave stage having a second slave data input coupled to an output of the inverter, a complementary slave data output, and a third bistable element; the third bistable element coupled between the second slave data input and the complementary slave data output, and being adapted to switch between states during the second edge of the clock signal in response to the state of the output signal of the inverter.

8. The memory system of claim 7, wherein a plurality of the flip-flops is adapted to serve as an output register of the digital data buffer.
